(19) United States
(12) Patent Application Publication
(10) Pub. No.: US 2012/0038432 A1
(43) Pub. Date: Feb. 16, 2012

(54) Wideband impedance matching of power amplifiers in a planar waveguide

(76) Inventor: M. Scott Andrews, Escondido, CA (US)

(21) Appl. No.: 13/135,886

(22) Filed: Jul. 14, 2011

Related U.S. Application Data
(60) Provisional application No. 61/364,218, filed on Jul. 14, 2010.

(51) Int. Cl. H03H 7/38

(52) U.S. Cl. 333/33

(57) ABSTRACT

A flexible matching circuit topology defined by rules maximizes transfer efficiency for an amplified input signal over a wide band of operation. The circuit includes an impedance matching circuit suitable for transforming an electromagnetic signal transmission path of a first impedance into an electromagnetic signal transmission path having a second impedance. A first transmission line element is connected to at least one intermediate transmission line element. At least one pair of perpendicularly juxtaposed transmission line stub elements are connected across said intermediate transmission line element. At least one last transmission line element is connected to the intermediate transmission line element. An optional number of single-sided stub elements may be connected perpendicularly to the first transmission line element, the intermediate transmission line elements or the last transmission line element.

### CROSS REFERENCE TO RELATED APPLICATIONS

This patent application claims priority of Provisional Patent Application 61/364,218 filed Jul. 14, 2010, the disclosure of which is incorporated by reference herein in its entirety.

### BACKGROUND OF THE PRESENT SUBJECT MATTER

1. Field of the Present Subject Matter

The present subject matter relates to dielectric waveguides such as microstrips or planar waveguides, and more specifically to impedance matching within a transmission line.

2. Background

One form of high-frequency, high-power, wideband amplifier is formed on a semiconductor substrate. In one context, a nominal power level is 100 W. Other power levels may be accommodated. The amplifier is coupled to an output terminal by a planar transmission line. The transmission line may comprise a microstrip. However, the present context is not limited to microwave frequency apparatus. The amplifier may provide power for any number of applications. Examples include communications and microwave oven power supply.

Of course, impedance matching of the amplifier to the transmission line is extremely important. In impedance mismatch causes power to be reflected. One measure of our reflection is VSWR, or voltage standing wave ratio. Reflected power is not provided to an output stage. The output stage can be an antenna directly, a circulator, diplexer, another amplifier, or many other forms of output stages. Efficiency is reduced, often significantly.

One conventional response to this problem is the use of adequate heat sinks or active cooling devices. While problems due to overheating or avoided, inefficiency remains.

Another approach is the inclusion of linearization electronics for amplifiers. Linearization techniques used in power amplifiers compensate for significant nonlinearity exhibited by, for example, transistors in power driving amplifier stages. Efficiency is improved results. However thermal run-away may still occur.

Impedance matching techniques may be very complex. For example, United States Patent Application Publication No. 20110143687 discloses a matching circuit in the context of a transmitter on a substrate. Several reactance circuits must be included to accomplish matching. Expense and complexity are increased with respect a circuit that utilizes a modified transmission line.

United States Patent Application Publication No. 20080136552 discloses a scheme for impedance matching due to wire bonding between a microstrip transmission line and a conductor backed coplanar waveguide. Here, the problem is addressed by use of particular materials rather than a particular geometry.

Accordingly, there exists a need for improving impedance matching in high power amplifier applications utilizing a transmission line on a dielectric substrate.

### SUMMARY

In accordance with the present subject matter, a structure is provided which allows a wideband width signal to propagate as a traveling wave across the matching circuit in such a way as to allow an amplifying device to operate simultaneously at peak efficiency and output power level. The foregoing, and various other needs, are addressed, at least in part, by the present subject matter, wherein power added efficiency is dramatically improved over an arbitrarily, seemingly limitless bandwidth via use of the matching circuit topology and design methods of the present subject matter.

According to one preferred form, a flexible matching circuit topology defined by rules is provided to maximize transfer efficiency for an amplified input signal over a wide band of operation. The circuit includes an impedance matching circuit suitable for transforming an electromagnetic signal transmission path of a first impedance into an electromagnetic signal transmission path having a second impedance. A first transmission line element is connected to at least one intermediate transmission line element. At least one pair of perpendicularly juxtaposed transmission line stub elements are connected across said intermediate transmission line element. At least one last transmission line element is connected to the intermediate transmission line element. An optional number of single-sided stub elements may be connected perpendicularly to the first transmission line element, the intermediate transmission line elements or the last transmission line element.

### BRIEF DESCRIPTION OF THE DRAWINGS

FIG. 1 is a plan view of a first form of transmission line for inclusion on a substrate utilizing a wideband matching circuit topology;

FIG. 2 is a plan view of a further form of transmission line;

FIG. 3 is a plan view illustrating further details of a wideband matching circuit topology;

FIG. 4 is a plan view of a further embodiment of transmission line incorporating wideband matching circuit topology;

FIG. 5 is a plan view of yet another form of wideband matching circuit topology which is in a transmission line;

FIG. 6 is an isometric view of a wideband matching circuit topology, which may include metal deposited on an insulating substrate material and a ground plane underneath the insulating substrate material;

FIG. 7 is a block diagram illustrating the use of the first embodiment wideband matching circuit topology of the present subject matter within an amplifying system;

FIG. 8 is a plan view useful in describing desired dimensions in a dimensions matching circuit topology;

FIG. 9 is a graph illustrating a nominal case of power added efficiency and output power performance of the amplifying apparatus according to the present subject matter; and

FIG. 10 is an isometric view of an embodiment comprising metal sandwiched between two insulating substrate materials and a ground plane above the upper insulating substrate material and underneath the lower insulating substrate material.

### DETAILED DESCRIPTION

It is to be understood that the present subject matter is not limited in its application to the details of construction and to the arrangements of the components set forth in the following description or illustrated in the drawings. The present subject matter is capable of other embodiments and of being practiced and carried out in various ways. Also, it is to be understood that the phraseology and terminology employed herein are for the purpose of description and should not be regarded as limiting.

Reference now will be made in detail to the presently preferred embodiments of the present subject matter. Such embodiments are provided by way of explanation of the present subject matter, which is not intended to be limited thereto. Various modifications and variations can be made.

For example, features illustrated or described as part of one embodiment can be used on other embodiments to yield a still further embodiment. Additionally, certain features may be interchanged with similar devices or features not mentioned yet which perform the same or similar functions. It is therefore intended that such modifications and variations are included within the totality of the present subject matter.

Prior art matching impedance stubs have been commonly and exclusively either of simple rectangular in shape or of semicircular (pie) in shape. The reflection behavior along the rectangular shape is represented mathematically as follows:

$$ρ = {ρ}_{0} {e}^{( 2 j β l )} \\ where \\ ρ ≡ reflection coefficient \\ β = \frac{2 π}{λ} ≡ propagation constant \\ l ≡ line length ( m ) \qquad ( 1 )$$

The impedance along on an open circuit straight rectangular stub that is juxtaposed to a transmission line of similar rectangular shape is given by:

Z_{OC}=−jZ₀ cot(β/l) (2)

The initial reflection as a function of impedance along an exponential tapered transmission line similar to the shapes presented in the present subject matter is given by:

$${ρ}_{0} = \frac{1}{2} ln ( \frac{{Z}_{OC}}{{Z}_{0} } ) \qquad ( 3 )$$

Upon substitution of expression (2) into expression (3) an initial reflection as function of impedance for an exponentially tapered open circuit stub is found as:

$${ρ}_{0} = \frac{1}{2} ln ( - j cot ( β / l ) ) \qquad ( 4 )$$

And by further substitution of expression (1) into expression (4) a general expression for open circuit stub reflection of an exponential taper as a function of propagation constant and line length is found as:

$$ρ = \frac{1}{2} ( {e}^{2 j β l} ) ln ( - j cot ( β / l ) ) \qquad ( 5 )$$

This expression shows high degree of frequency dependent variability and when juxtaposed to a transmission line of similar characteristics, a very rich set of frequency modes may exist on the waveguide structure represented by the preferred embodiment.

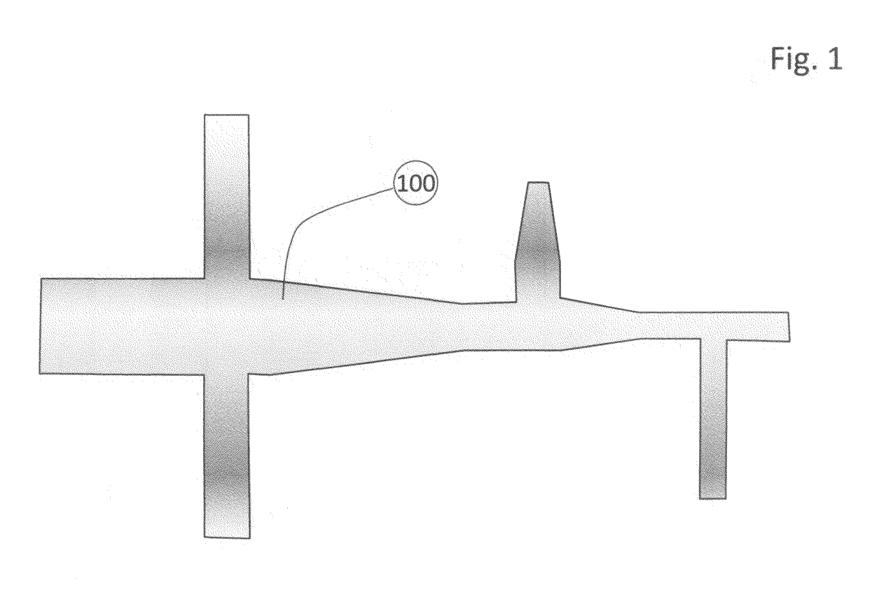

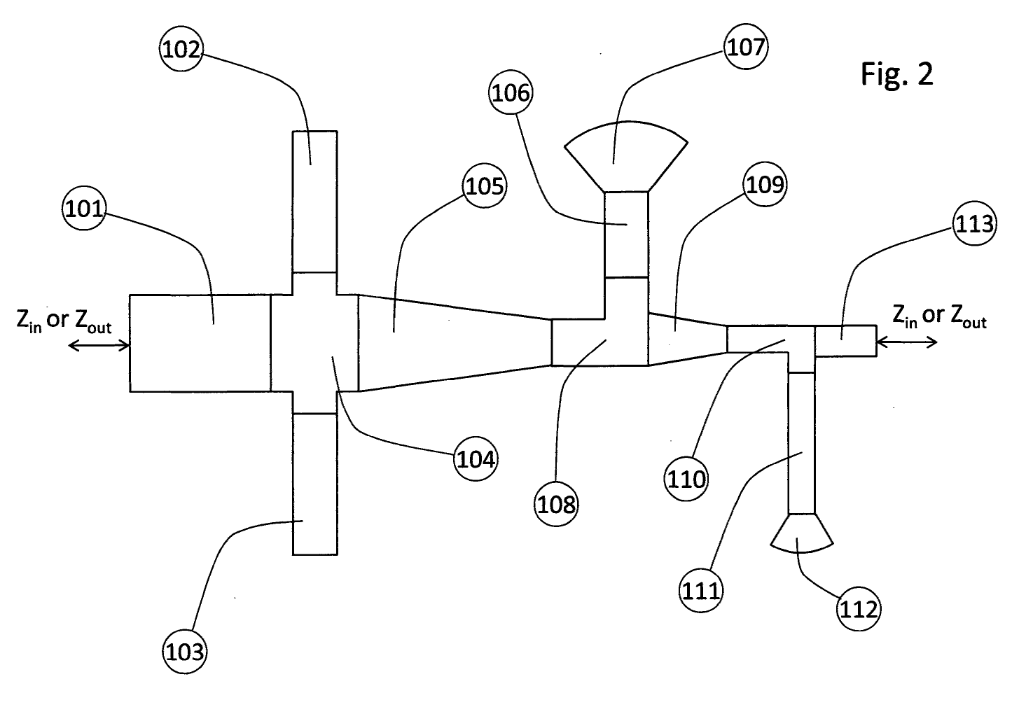

FIG. 1 is a plan view of an exemplary transmission line 100 embodying matching circuit topology according to the present subject matter. The transmission line is designed for improving power transfer efficiency over a very wide bandwidth and at a prescribed power level. Further features and embodiments are described in further detail with respect to FIGS. 2-5.

FIG. 2 is a plan view of a further form of transmission line. As shown in FIG. 2 from the left, a receiving or transmitting signal generated from an external signal source enters or exits a first transmission line element 101, which has a specific characteristic impedance value. In the case of an entering, or source, wave, a traveling wave is further propagated across element 104. For purposes of the present description, the wave propagated across junction is referred to as a propagating wave. The propagating wave sets up a non-uniform standing wave between a pair of resonance stub elements 102 and 103. At the stub elements 102 and 103, the propagating standing wave's power and frequency characteristics are modified. Propagation continues into a long and tapered edge intermediate transmission line element 105, where the power and frequency characteristics of the standing wave are further modified. The standing wave continues along an L-shaped junction element 108. The designation L is arbitrary. The junction 108 which could alternatively be described as a T-shaped or cross shaped junction element. At the L-shaped junction element 108 may be coupled to a non-uniform standing wave resonance tuning element, which in the present illustration comprises a single-sided tuning stub 106 and 107. Inclusion of the non-uniform standing wave resonance tuning element is optional.

The standing wave is further propagated along a second tapered edge intermediate transmission line element 109, where its power and frequency characteristics are again modified. The standing wave propagates along L-shaped junction element 110. The designation L is arbitrary. The junction element 110 could alternatively be described as a T-shaped or cross shaped junction element. The standing wave also propagates across single-sided tuning stubs 111 and 112. The standing wave is again modified in frequency and power characteristic before reaching a final transmission line element 113. The final transmission line element 113 has a specific characteristic impedance value, almost assuredly different from that specific to the first transmission line element, 101.

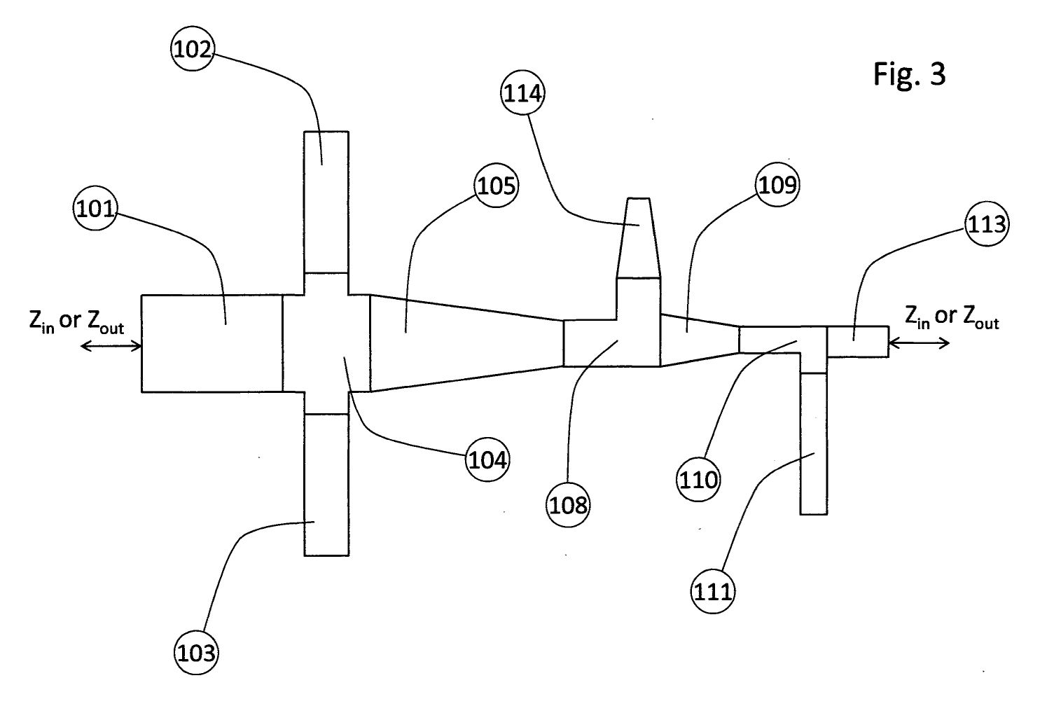

It is important to note that the characteristic impedance value of any previously described element of the matching circuit topology is variable throughout the topology. It is likewise important to note that the standing wave propagating throughout the matching circuit topology is essentially bi-directional. A transmission and a reflection aspect of the propagating wave simultaneously exist. Transmission line element geometry directs a wave along the direct transmission path, i.e., the horizontal signal propagation path as seen in FIG. 1. Various resonance members connect to the transmission line vertically as seen in FIG. 1, perpendicular to the transmission path. These comprise perpendicular tuning stubs of various forms and geometry. At least one of the perpendicularly juxtaposed transmission line stubs or said single-sided stub elements is open circuit or shunt circuit configured. Additional variations illustrating this unique combination exist and a partial list of exemplary embodiments will now be illustrated by FIGS. 3, 4, and 5.

“Perpendicular” is used here as a nominal specification. It need not mean exactly 90°. Deviation from 90° tends to degrade preference. Performance characteristics can be measured, and a user can select a maximum permissible level of degradation.

FIG. 3 is a plan view illustrating further details of a wideband matching circuit topology. FIG. 3 illustrates the details of a second exemplary embodiment in accordance with one or more embodiments of the present subject matter. The main difference between the circuit of FIG. 2 and the circuit of FIG. 3 is in the substitution of tuning stub elements 106 and 107 with tuning stub element 114 and modification of resonance tuning elements 111 and 112 by deletion of element 112.

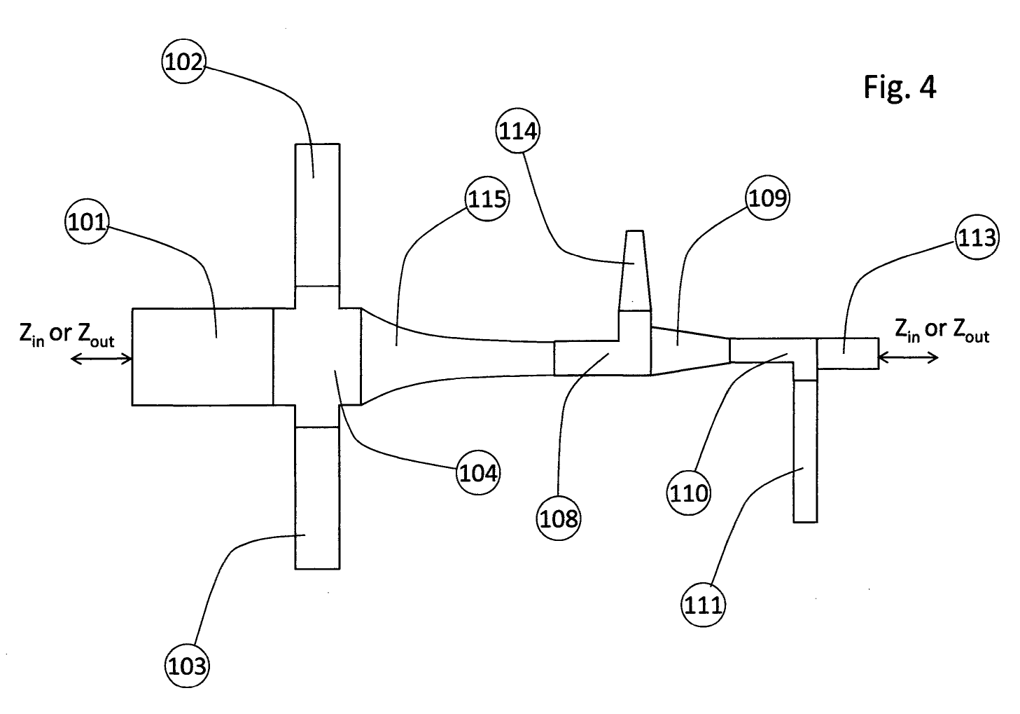

FIG. 4 is a plan view illustrating the details of a third exemplary embodiment in accordance with one or more embodiments of the present subject matter. The circuit of FIG. 4 comprises a non-linear intermediate transmission line element 115 rather than the linear tapered intermediate transmission line element 105 of FIG. 3.

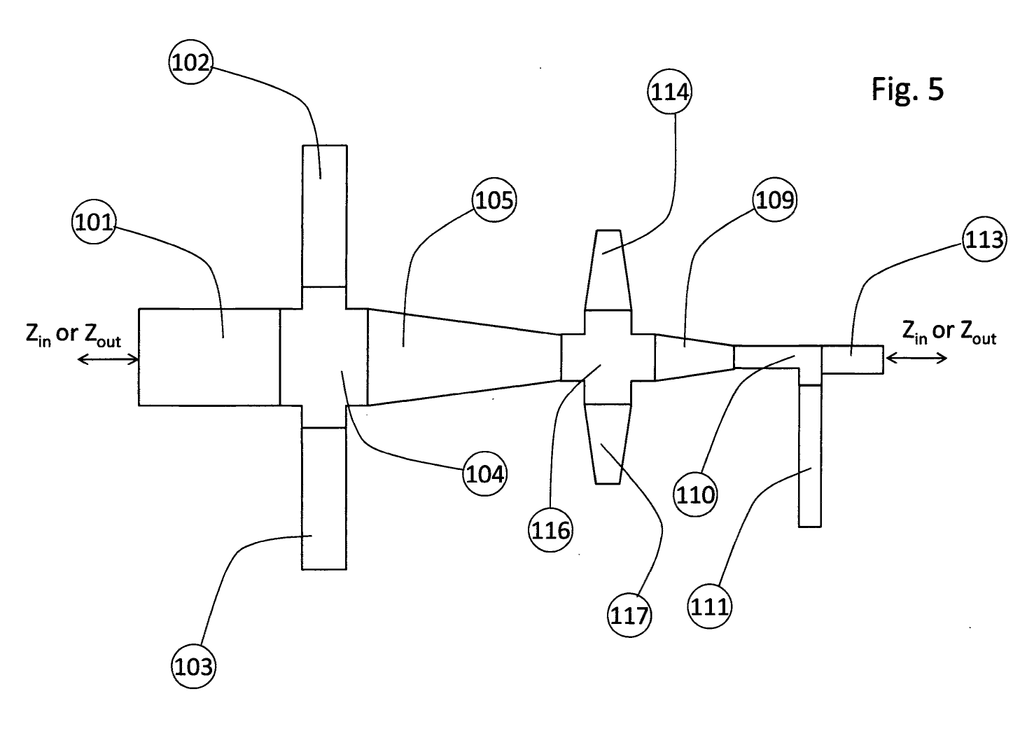

FIG. 5 is a plan view of yet another form of wideband matching circuit topology in a transmission line. A cross shaped junction element 116 and associated additional juxtaposed tuning stub, 117 are utilized in the alternative to the L-shaped junction element 108 of FIG. 3.

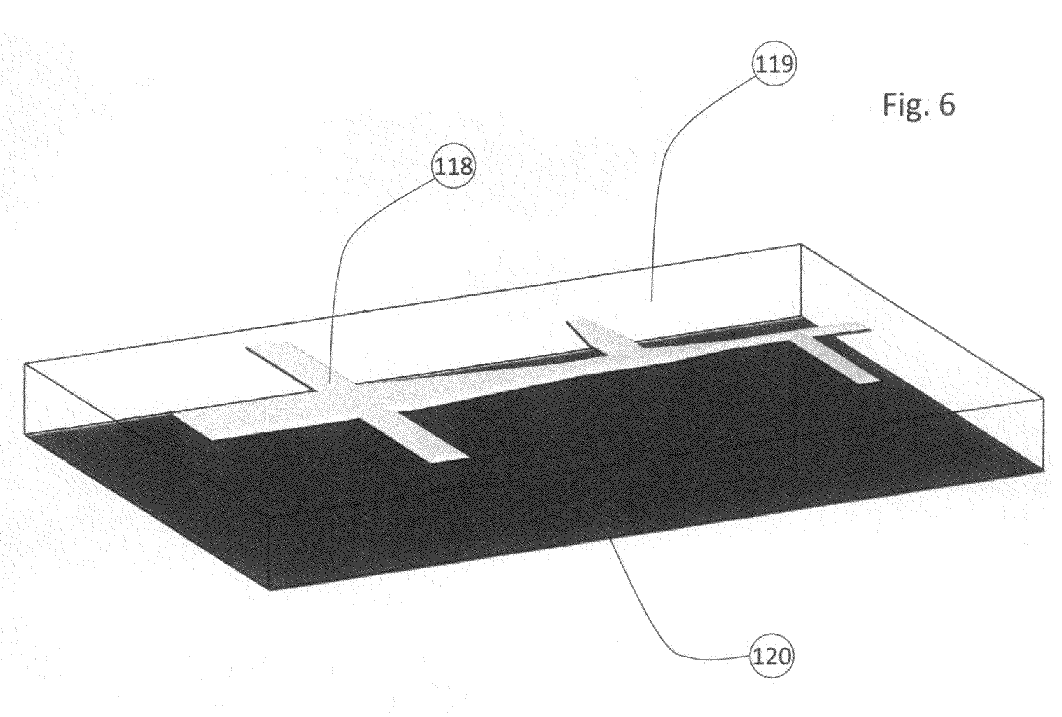

FIG. 6 is an isometric view of a wideband matching circuit topology, which may include metal deposited on an insulating substrate material and a ground plane underneath the insulating substrate material. The embodiment of FIG. 6 comprises the transmission line 100 of FIG. 1 on a substrate 119. The transmission line 118 comprises the metallization layer on top of the insulating substrate 119, which comprises a dielectric material. A metallic ground, or reference, plane 120 is formed at a lower, preferably planar, surface of the substrate 119. The ground plane 120 is used to support the travelling wave within the medium.

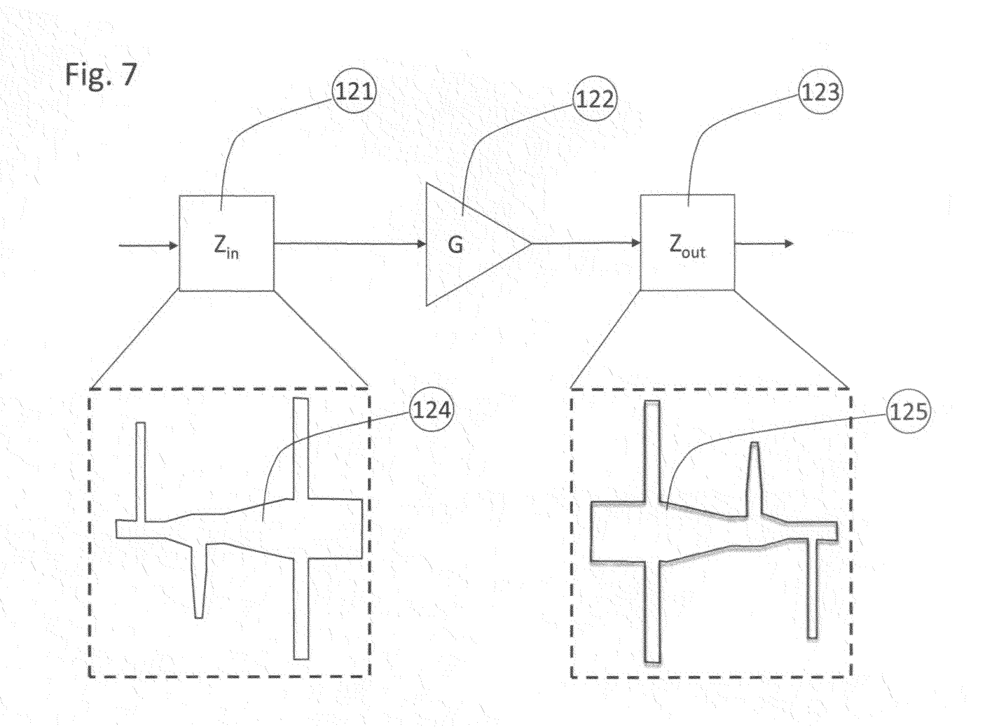

FIG. 7 is a block diagram illustrating the use of the first embodiment wideband matching circuit topology of the present subject matter within an amplifier system. FIG. 7 represents a use of the present subject matter within an amplifier system. The amplifier system comprises an input impedance matching circuit 121/124, an active device 122, and an output impedance matching circuit 123/125. The geometries of the impedance matching circuits used for input and output impedance matching of the amplifying apparatus are not necessarily commensurate in geometry or in size.

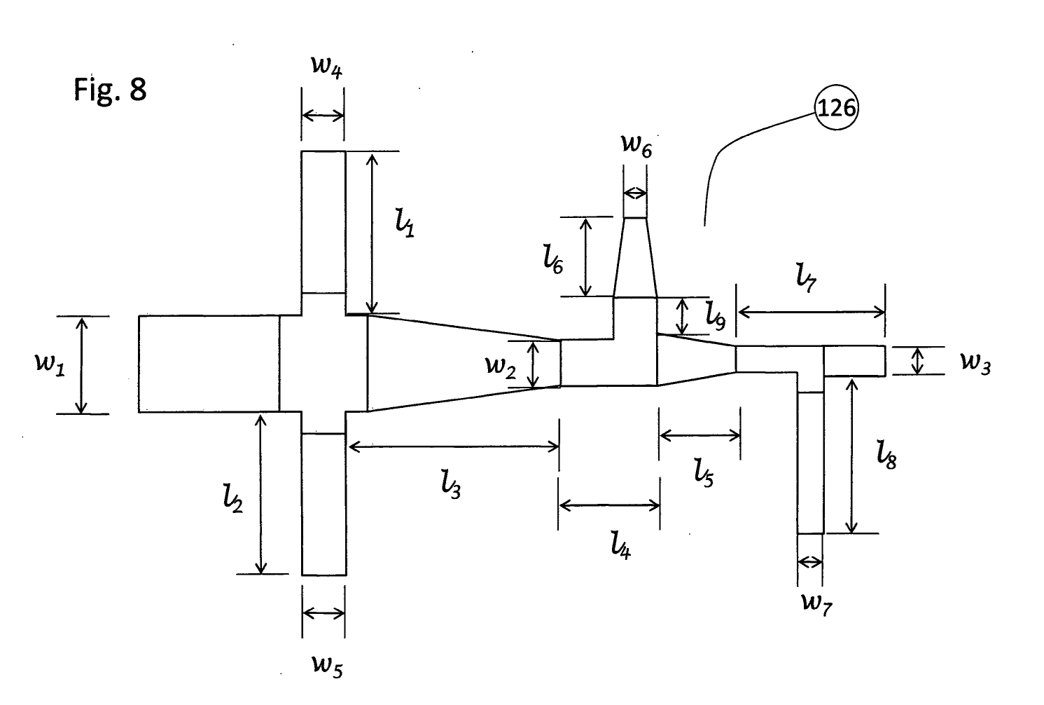

FIG. 8 is a plan view useful in describing desired dimensions in a dimensions matching circuit topology. FIG. 8 illustrates a series of lengths and widths 126 used to specify some of the geometry of each of the individual elements of the wideband matching circuit topology from exemplary embodiment of the present subject matter illustrated by FIG. 3. Lengths and widths to provide a center frequency of operation can be calculated from known principles. The impedance transformation required can be measured or otherwise calculated.

The frequency of operation corresponds to a particular wavelength. The resonant stubs are sized to correspond to a selected fraction, e.g., ¼, of the standing wave wavelength. Widths are specified according to the impedance transformation needed. Such prior art was more narrowband due to dependence on a center frequency of operation. In the present subject matter, the prior art requirement to be dependent on a single center frequency is lost in favor of choosing through some other means the various dimensions of the circuit to represent a much larger number of frequencies over which the circuit may operate.

A computer tuning and optimization algorithm in a computer program may be used to calculate the desired dimensions of the circuit elements. One program is Microwave Office published by Applied Wave Research Corporation. A user may input frequency design specification frequency. Additionally, the user may input an approximate dimension. In many cases ¼ wavelength is a useful dimension. Also, the program can be informed of the user's design criteria. The program will calculate tradeoffs and optimize an element design to maximize the level of the parameter sought most by the user. Parameters may include maximum power level, efficiency, or other parameters. The program will provide an output indicating shapes and dimensions of elements cooperating with the transmission line. These dimensions and shapes comprise elements formed in a rule-based geometry. Another suitable program is Advanced Design System by Agilent Technologies.

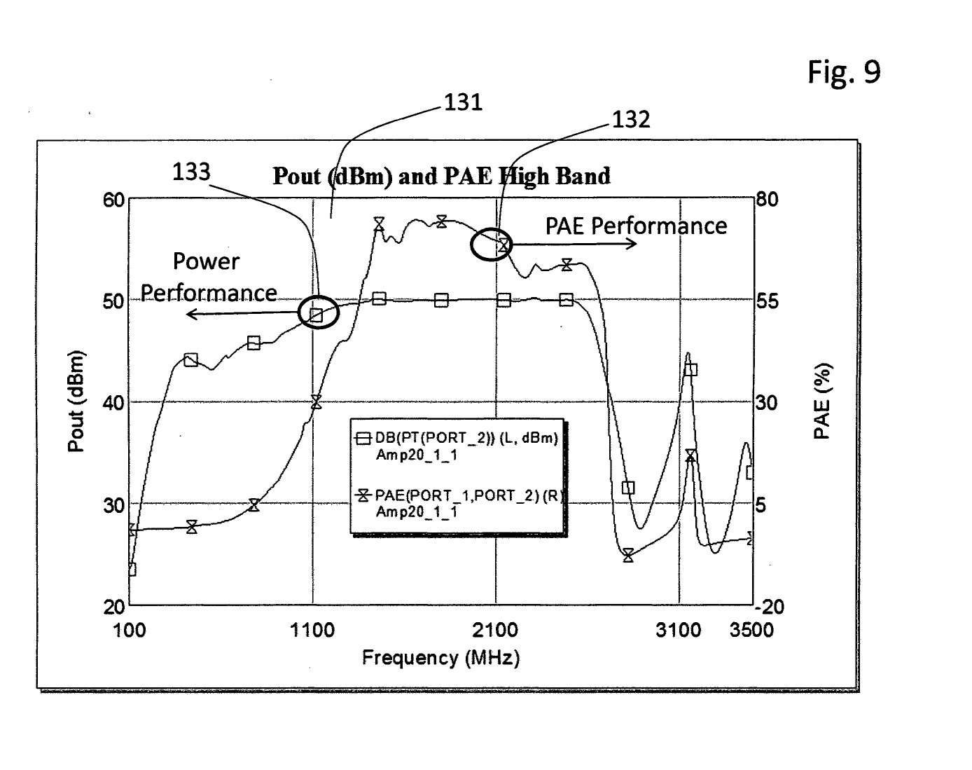

FIG. 9 illustrates by way of example a performance graph 131 showing the PAE 132 and power 133 performances of an actual amplifying apparatus built in correspondence with the embodiment of FIG. 7 using an actual wideband matching circuit topology. This amplifying apparatus exhibits wideband behavior in terms of output power and efficiency of operation.

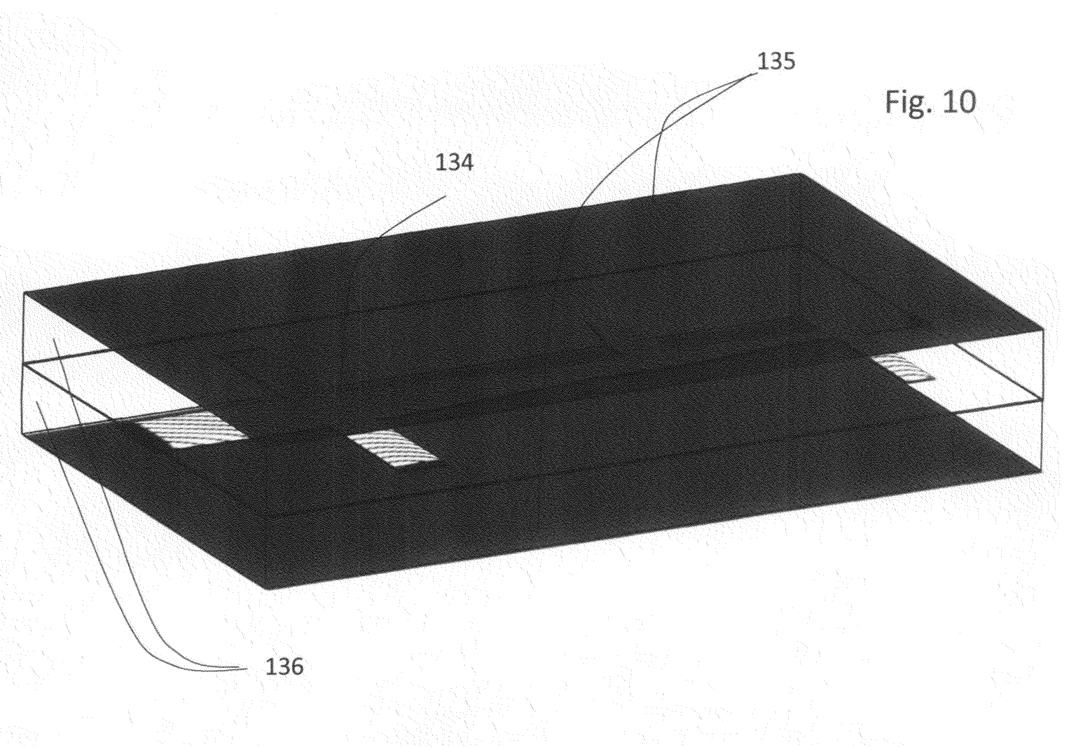

FIG. 10 is an isometric view of an embodiment comprising metal sandwiched between two insulating substrate materials and a ground plane above the upper insulating substrate material and underneath the lower insulating substrate material. FIG. 10 illustrates by way of example a performance graph 131 showing the power added efficiency (PAE) 132 and power 133 performances of an actual amplifying apparatus as illustrated in FIG. 7 using an actual exemplary wideband matching circuit topology not unlike the exemplary embodiment described by FIG. 4. This amplifying apparatus exhibits wideband behavior in terms of output power and efficiency of operation.

FIG. 10 illustrates another embodiment by which designs with the features represented by the present subject matter may also be fabricated. FIG. 10 is an isometric view of an alternative embodiment to that of FIG. 1. FIG. 10 comprises a wideband matching circuit in a sandwiched physical embodiment. Transmission line 134 illustrates the metallization layer in-between a top and bottom insulating substrate components, 136 composed of a dielectric material, and 135 represents a metallic ground, or reference, plane used to support the travelling wave within the medium.

Those skilled in the art will appreciate that the present subject matter may readily be utilized as a basis for the designing of other structures, methods, and systems for carrying out the several purposes of the present subject matter. It is important, therefore, that the claims be regarded as including such equivalent constructions insofar as they do not depart from the spirit and scope of the present subject matter.

What is claimed is:

1. A wideband impedance matching circuit in a planar waveguide comprising: a first transmission line element connected to at least one intermediate transmission line element, at least one pair of perpendicularly juxtaposed transmission line stub elements across said intermediate transmission line element, at least one last transmission line element connected to said intermediate transmission line element, and an optional number single-sided stub elements perpendicularly connected to said first transmission line element, said intermediate transmission line elements or said last transmission line element.

2. The wideband impedance matching circuit of claim 1 comprising a substrate and wherein all of said elements are formed on the substrate.

3. The wideband impedance matching circuit of claim 2 wherein said elements comprise a conductive metal.

4. The wideband impedance matching circuit of claim 3 wherein each said element is formed in a rule-based geometry to accommodate preselected frequencies.

5. The wideband impedance matching circuit of claim 4 wherein at least one of said perpendicularly juxtaposed transmission line stubs or said single-sided stub elements is open circuit or shunt circuit configured.

6. The wideband impedance matching circuit as claimed in 1 in which any or all of said perpendicularly juxtaposed transmission line stubs or said single-sided stub elements are of disproportionate area with respect to each other.

7. The wideband impedance matching circuit of claim 1 in which at least one of said first transmission line element, said intermediate transmission line element, said pair of perpendicular juxtaposed stub elements, said optional single-sided stub elements, or said last transmission line element have tapered edges.

8. The wideband impedance matching circuit of claim 7 wherein at least one of said transmission line elements or stub elements comprises tapered edges, whereby the tapering is specified by a mathematical function comprising a line, a polynomial, a logarithmic, an exponential, or a transcendental mathematical function.

9. The wideband impedance matching circuit of claim 1 further comprising an active device coupled thereto.

10. The wideband impedance matching circuit of claim 9 wherein said active device comprises a transistor.

11. The wideband impedance matching circuit of claim 10 wherein said active device comprises an amplifier.

12. A wideband impedance matching circuit comprising a planar dielectric waveguide having a microstrip transmission line formed thereon, and further comprising stub elements connected thereto to match impedance.

13. The wideband impedance matching circuit of claim 12 where each stub element is dimensioned to correspond to a preselected fraction of an operating wavelength.
